(19) United States
(12) Patent Application Publication
(10) Pub. No.: US 2010/0232112 A1
(43) Pub. Date: Sep. 16, 2010

(54) Semiconductor module

(75) Inventors: Tatsuyuki Uechi, Toyoake (JP); Hiromichi Agata, Nishio (JP); Kazuo Aoki, Anjo (JP); Tomoo Atarashi, Kariya (JP); Masahiro Tanae, Okazaki (JP)

Correspondence Address: OLIFF & BERRIDGE, PLC, P.O. BOX 320850, ALEXANDRIA, VA, 22320-4850, US

(73) Assignee: AISIN AW CO., LTD., Anjo-Shi (JP)

(21) Appl. No.: 12/656,235

(22) Filed: Jan. 21, 2010

(30) Foreign Application Priority Data
Mar. 12, 2009 (JP) 2009-059251

(51) Int. Cl. H05K 7/20; H05K 7/00

(52) U.S. Cl. 361/704; 361/728

(57) ABSTRACT

A semiconductor module includes a base plate whose one surface is formed with a fin region in which a cooling fin is provided; a substrate that is disposed on the other surface of the base plate and provided with a switching device; and a case member having an internal space an opening formed in one wall of the case member so that the opening is smaller than the one surface of the base plate and larger than the fin region.

### INCORPORATION BY REFERENCE

The disclosure of Japanese Patent Application No. 2009-059251 filed on Mar. 12, 2009 including the specification, drawings and abstract is incorporated herein by reference in its entirety.

### BACKGROUND

The present invention relates to a semiconductor module that includes a base plate, a substrate disposed on one surface of the base plate and provided with a switching device, and a case member.

A known example of such semiconductor modules is a semiconductor module that includes a base plate, a substrate disposed on one surface of the base plate and provided with a switching device, a case provided on the base plate so as to surround the substrate, and a cooling medium flow path provided so as to be in contact with the other surface of the base plate (e.g., Japanese Patent Application Publication No. JP-A-2008-294069 (Paragraphs [0026], [0042], and FIG. 8)). In this semiconductor module, bolt fastening holes are respectively provided at four corners of the case, and the case is fixed on the base plate by inserting and screwing bolts into the bolt fastening holes.

### SUMMARY

In such a conventional semiconductor module as shown in Japanese Patent Application Publication No. JP-A-2008-294069 (Paragraphs [0025], [0026], [0042], and FIG. 8), the case member is fixed to the base plate by fastening the bolts. Thus, the size of the semiconductor module is necessarily increased in a lateral direction by an amount corresponding to the bolt heads.

It is an object of the present invention to provide a technique of avoiding an increase in size of semiconductor modules in related art, while ensuring the connection strength between a base plate and a case member.

In order to achieve the above object, a semiconductor module according to a first aspect of the present invention includes: a base plate whose one surface is formed with a fin region in which a cooling fin is provided; a substrate that is disposed on the other surface of the base plate and provided with a switching device; and a case member having an internal space and an opening formed in one wall of the case member so that the opening is smaller than the one surface of the base plate and larger than the fin region. In the semiconductor module, the fin formed on the base plate protrudes from an internal space side to outside through the opening of the case member, and the one surface of the base plate is hermetically bonded with a surface of the one wall on the internal space side, and the case member, the substrate, and the base plate are fixed by filling the internal space of the case member with a resin.

According to this structure, no bolt-fastening through hole need be formed in the case member, and the size of the semiconductor module can be prevented from increasing in the lateral direction by the space occupied by the heads of bolts inserted in the respective through holes. Moreover, the base plate is fixedly bonded to the case member with only the fin region of the base plate protruding from the internal space side of the case member. Thus, by filling the internal space of the case member with a resin and curing the resin, a force that is applied from the outside of the case member to the base plate is received by the case member, and a force in the opposite direction is received by the resin filling the internal space. Thus, the bonding strength between the case member and the base plate becomes sufficiently high. Note that the internal space is filled with the resin in order to improve the vibration resistance of the switching device and to improve the insulation property, and such resin filling is required not only in the structure of the present invention. Thus, an increase in cost caused by the resin filling need not be considered.

In one preferred embodiment of the present invention, the case member is made of a resin, whereby the bonding strength between the case member and the resin filling the internal space is increased, and the overall strength of the semiconductor module is also increased. Moreover, since insulation capability from the substrate is improved, the case member itself can be reduced in size. In the case of using the structure in which the case member is made of a resin and the base plate is made of a metal, the base plate and the case member may be hermetically bonded by a metal-resin adhesive. In this case, since the metal plate is made of a metal, the strength is increased, and the cooling capability is improved.

In order to form, e.g., a cooling medium passage for effectively cooling the fin formed on the base plate, a metal case is connected to a surface of the one wall of the case member on a side opposite to the internal space. The metal case and the bottom wall of the case member may be also connected by hermetic bonding. Thus, since the base plate, the case member, and the metal case are integrated by hermetic bonding, the above problem in related art is also solved in the semiconductor module of the present invention formed by the base plate, the case member, and the metal case.

In one preferred embodiment of the semiconductor module formed by the base plate, the case member, and the metal case, a wall surface of the metal case is formed to be uneven, and the metal case and the case member are hermetically bonded by performing bonding for integrating a resin and a metal by which the injection molded resin and the uneven wall surface are bonded with each other when injection molding the case member. Integration bonding called a “nano-molding technology (NMT)” may be used as this integration bonding, especially when the metal is aluminum. In the NMT, the surface of aluminum is modified by a special treatment, and a hard resin is applied to the uneven surface at nano size, thereby integrating aluminum and the resin. Thus, the case member is formed on the metal case by injection molding a resin directly on the uneven surface of the metal case, whereby the case member and the metal case are integrated. The case member and the metal case are completely sealed, and the bonding strength thereof is sufficient for the semiconductor module.

In another preferred embodiment of the semiconductor module formed by the base plate, the case member, and the metal case, a through hole is provided in the one wall of the case member, a wedge recess, which communicates with the through hole to form a wedge shape, is provided in a wall surface of the metal case that corresponds to the through hole, and the case member and the metal case are hermetically bonded by a wedge-shaped joint that is formed by filling the through hole and the wedge recess with a resin. In this embodiment, the resin, which fills the through hole and the wedge recess, forms the wedge shape in a bonding region between the case member and the metal case, whereby the bonding strength is increased. Moreover, such resin filling can be performed simultaneously with the resin filling of the internal space, which is advantageous in terms of the cost and the manufacturing technology.

In still another preferred embodiment of the semiconductor module formed by the base plate, the case member, and the metal case, a through hole is provided in the metal case, a screw hole is provided in a wall surface of the case member that corresponds to the through hole, and the metal case and the case member are hermetically bonded by a sealant and screw fastening. In this embodiment, since the screw fastening is used, substantially the same bonding strength as that obtained by conventional bolt connection is obtained between the metal case and the case member. At the same time, an increase in size of the case member in the lateral direction, which is caused by the bolt heads, is avoided by connecting the metal case and the case member by screw fastening from the metal case side.

### BRIEF DESCRIPTION OF THE DRAWINGS

FIG. 1 is a plan view schematically showing the structure of a main part of a semiconductor module according to an embodiment of the present invention;

FIG. 2 is a cross-sectional view taken along line II-II in FIG. 1;

FIG. 3 is a cross-sectional view taken along line in FIG. 1;

FIG. 4 is a circuit diagram of an inverter circuit incorporated in the semiconductor module of FIG. 1;

FIG. 5 is a cross-sectional view corresponding to FIG. 3, schematically showing the structure of a main part of a semiconductor module according to another embodiment of the present invention;

FIG. 6 is a cross-sectional view corresponding to FIG. 3, schematically showing the structure of a main part of a semiconductor module according to still another embodiment of the present invention; and

FIG. 7 is a cross-sectional view corresponding to FIG. 3, schematically showing the structure of a main part of a semiconductor module according to yet another embodiment of the present invention.

### DETAILED DESCRIPTION OF EMBODIMENTS

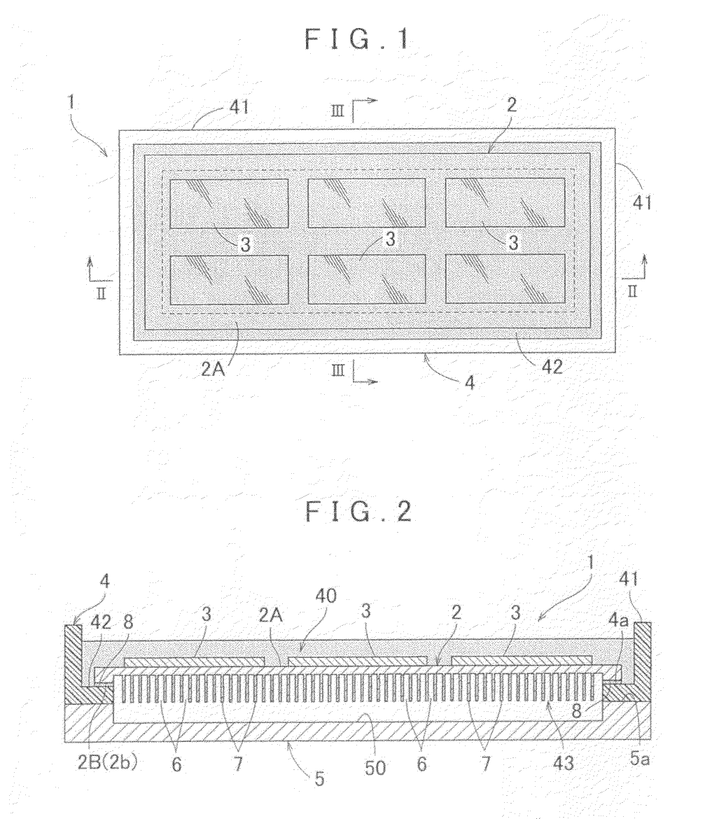

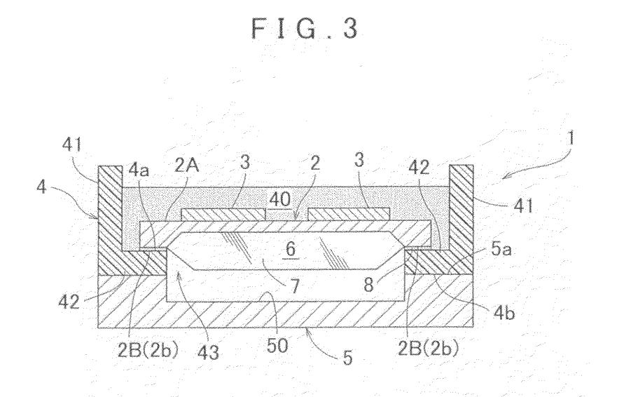

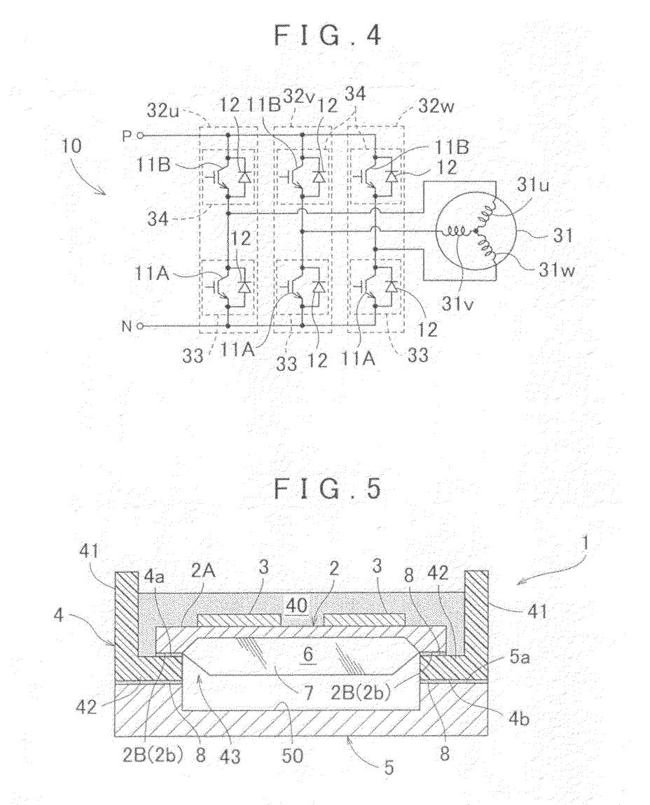

An embodiment of the present invention will be described with reference to the accompanying drawings. The present embodiment will be described with respect to an example in which the present invention is applied to a semiconductor module 1 as an inverter apparatus of a three-phase alternating current (AC) inverter circuit. FIG. 1 is a plan view schematically showing the structure of a main part of the semiconductor module 1 according to the present embodiment. FIG. 2 is a cross-sectional view taken along line II-II in FIG. 1. FIG. 3 is a cross-sectional view taken along line in FIG. 1. FIG. 4 is a circuit diagram of an inverter circuit incorporated in the semiconductor module 1.

As shown in FIGS. 2 and 3, this semiconductor module 1 includes: a base plate 2; substrates 3 disposed on an upper surface 2A of the base plate 2; a case member 4 having a peripheral wall 41 surrounding the substrates 3, and a bottom wall 42 as one wall supporting a lower surface 2B of the base plate 2; and a metal case 5 positioned on a lower surface of the bottom wall 42 of the case member 4. Although described in detail below, a bonding lower surface portion 2b of the base plate 2, and a bonding upper surface 4a of the case member 4 are hermetically bonded together, and a bonding lower surface 4b of the case member 4 and a bonding upper surface 5a of the metal case 5 are hermetically bonded together. Note that, in the present embodiment, the lower surface 2B of the base plate 2 corresponds to one surface in the present invention, and the upper surface 2A thereof corresponds to the other surface in the present invention.

As shown in FIG. 4, the semiconductor module 1 forms an inverter circuit 10 for driving a three-phase AC electric motor 31. Thus, as shown in FIG. 1, six substrates 3, each having a switching device 11 and a diode device 12, are disposed on the upper surface 2A of the base plate 2. Note that, although a control substrate for performing, for example, operation control of the switching devices 11 on each substrate 3 is positioned above the substrates 3, and is supported by the case member 4 in this semiconductor module 1, the control substrate is not shown in the drawings.

The semiconductor module 1 forms cooling medium flow paths 6 for cooling especially the switching devices 11 that generate the largest amount of heat. The cooling medium flow paths 6 are formed by positioning a plurality of fins 7 in a cooling medium flow recess 50 that serves as a cooling medium chamber provided in the metal case 5. The cooling medium flow paths 6 form parallel cooling medium flow paths in a predetermined direction in the cooling medium flow recess 50. The plurality of fins 7 are positioned parallel to each other along the lower surface 2B of the base plate 2. Each fin 7 is shaped like a plate standing vertically to the lower surface 2B of the base plate 2 and having a predetermined thickness, and is formed integrally with the base plate 2 by, e.g., cutting the lower surface 2B of the base plate 2. Moreover, the intervals at which the plurality of fins 7 are disposed are substantially the same, and the plurality of fins 7 has the same height.

As shown in FIGS. 1, 2, and 3, the base plate 2 is supported by the metal case 5 with the bottom wall 42 of the case member 4 interposed therebetween. An opening 43 is formed in a middle region of the bottom wall 42 of the case member 4, where the opening 43 is large enough to allow a fin region, where the plurality of fins 7 are formed, to exactly fit therein. This opening 43 communicates with an internal space 40 that is defined by the bottom wall 42 and the peripheral wall 41. By inserting the fins 7 of the base plate 2 into the opening 43 from the internal space 40 side, a plurality of parallel cooling medium flow paths are formed in the cooling medium chamber formed by the opening 43 and the cooling medium flow recess 50 of the metal case 5. Note that, although there is a space between the fins 7 and a bottom surface of the cooling medium flow recess 50 in FIGS. 2 and 3, the gap between the respective tips of the fins 7 and the bottom surface of the cooling medium flow recess 50 may be substantially zero. That is, the present invention may use a structure in which the tips of the fins 7 and the bottom surface of the cooling medium flow recess 50 are positioned close to each other so as to be in contact with each other. Note that, although a cooling medium inlet path into the cooling medium chamber and a cooling medium outlet path from the cooling medium chamber are formed in the metal case 5, the cooling medium inlet path and the cooling medium outlet path are not shown in the drawings.

An electric structure of the inverter circuit 10 incorporated in the semiconductor module 1 of the present embodiment will be described below. As shown in FIG. 4, the inverter circuit 10 is a circuit for driving the three-phase AC electric motor 31. That is, the inverter circuit 10 has a U-phase arm 32u, a V-phase arm 32v, and a W-phase arm 32w (corresponding to a U-phase, a V-phase, and a W-phase, respectively), which are provided corresponding to a U-phase coil 31u, a V-phase coil 31v, and a W-phase coil 31w of the three-phase AC electric motor 31, respectively. Each of the arms 32u, 32v, 32w for the respective phases has a pair of lower and upper arms 33, 34, which are capable of operating in a complementary manner. Each lower arm 33 has a lower arm switching device 11A formed by an npn type insulated gate bipolar transistor (IGBT) device, and a diode device 12 connected in parallel between an emitter and a collector of the lower arm switching device 11A. Similarly, the upper arm 34 has an upper arm switching device 11B formed by an npn type IGBT device, and a diode device 12 connected in parallel between an emitter and a collector of the upper arm switching device 11B. Anode of each diode device 12 is connected to the emitter of a corresponding one of the switching devices 11A, 11B, and cathode of each diode device 12 is connected to the collector of a corresponding one of the switching devices 11A, 11B.

The pair of lower and upper arms 33, 34 for each phase are connected in series so that the lower arm 33 is connected to a negative electrode N side as a ground, and the upper arm 34 is connected to a positive electrode P side as a power supply voltage. More specifically, the emitter of each lower arm switching device 11A is connected to the negative electrode N, and the collector of each upper arm switching device 11B is connected to the positive electrode P. That is, each lower arm switching device 11A serves as a lower-side switch, and each upper arm switching device 11B serves as a higher-side switch. In each arm 32u, 32v, 32w for each phase, the collector of the lower arm switching device 11A and the emitter of the upper arm switching device 11B are connected to a corresponding one of the U-phase coil 31u, the V-phase coil 31v, and the W-phase coil 31w of the electric motor 31.

The case member 4 is formed by the rectangular bottom wall 42, whose planar shape has the same size as that of the metal case 5, and the peripheral wall 41 standing along the entire circumference of the bottom wall 42. The internal space 40 is formed inside the case member 4. The internal space 40 is designed to have a larger transverse sectional shape than that of the base plate 2. As described above, the opening 43 formed in the bottom wall 42 is designed to have a transverse sectional shape that is smaller than that of the base plate 2, but larger than the planar shape of the fin region that is defined by the plurality of fins 7 formed on the lower surface 2B of the base plate 2. Thus, the fins 7 on the base plate 2 can be made to protrude from the internal space side to the outside through the opening 43 of the case member 4. The bottom wall 42 of the case member 4 is hermetically bonded with the bonding lower surface portion 2b of the base plate 2, which faces the bottom wall 42. In the present embodiment, the case member 4 is made of a resin, and the base plate 2 is made of copper. Thus, this hermetic bonding is performed with a metal-resin adhesive for bonding copper and a resin together. Reference numeral 8 indicates an adhesive layer formed by the metal-resin adhesive, and in the drawings, this adhesive layer is exaggerated for clarity.

Note that polyphenylene sulfide (PPS), cross-linked polyethylene (CV), or the like is used as a resin for the case member 4. In any case, various silicone, acrylic, and epoxy adhesives, which also function as a sealant when cured, are suitable as the metal-resin adhesive used herein. In particular, an adhesive, which has a property capable of adapting to the difference in thermal expansion coefficient between the case member 4 and the base plate 2, is preferable, and a silicone adhesive is especially suitable in this regard. Eventually, the internal space 40 is filled with a filler, such as an epoxy resin, and the filler is cured, whereby the six substrates 3 disposed on the base plate 2, and the case member 4 are integrated together.

Note that, in this embodiment, the metal case 5 is made of aluminum. Thus, the case member 4 is formed on the metal case 5 by using a nano-molding technology (NMT). That is, the surface of the metal case 5 is modified to be uneven at nano size by a special treatment, and a resin is directly injection molded to the uneven surface of the metal case 5, thereby integrating the aluminum metal case 5 and the resin case member.

It should be noted that it is also possible to form the case member 4 with a resin in advance, and to hermetically bonding the case member 4 and the metal case 5 by a metal-resin adhesive as shown in FIG. 5, as in the case of the bonding between the base plate 2 and the case member 4. In the drawing, an adhesive layer 8 formed between the metal case 5 and the case member 4 is also exaggerated for clarity. Either the same adhesive as that used to hermetically bond the case member 4 and the base plate 2, or a different adhesive may be used as an adhesive for bonding the metal case 5 and the case member 4. The use of a different adhesive is advantageous in that an adhesive having an intermediate thermal expansion coefficient between the thermal expansion coefficients of the case member 4 and the metal case 5 can adapt to the difference in thermal expansion coefficient between the case member 4 and the metal case 5.

### OTHER EMBODIMENTS

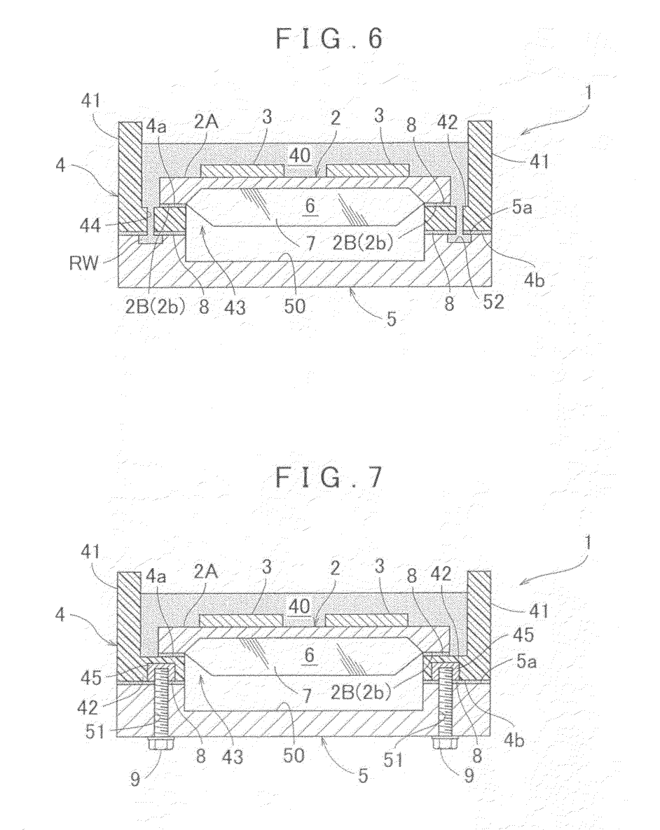

(1) Hermetic bonding between the case member 4 and the metal case 5 is not limited to bonding for integrating a resin and a metal (aluminum) by the NMT, and bonding by a metal-resin adhesive, as described above. For example, as shown in FIG. 6, a latching structure of a geometric shape may be used by filling a bonding region between the case member 4 and the metal case 5 with a resin in a wedge shape. That is, through holes 44 are provided in the bottom wall 42 of the case member 4, and wedge recesses 52 are provided in a peripheral wall upper surface 5a of the metal case 5, which corresponds to the through holes 44, where the wedge recesses 52 have a larger transverse section than that of the through holes 44 so as to form a wedge shape when communicating with the respective through holes 44. Wedge-shaped resin bodies RW are formed by bonding the peripheral wall upper surface 5a and the lower surface of the bottom wall 42 of the case member 44 by a metal-resin adhesive, and filling the through holes 44 and the wedge recesses 52 with a resin. The bonding strength is increased by the mutual effect of the wedge-shaped resin bodies RW and the adhesive layer 8. Note that performing the resin filling of the through holes 44 and the wedge recesses 52 simultaneously with the resin filling for integrating the substrates 3 and the case member 4 is advantageous in terms of the manufacturing process.

Still another hermetic bonding structure of the case member 4 and the metal case 5 is shown in FIG. 7. In this hermetic bonding structure, wedge through holes 51 are provided in a peripheral wall region of the metal case 5, and screw hole portions 45 corresponding to the respective wedge through holes 51 are provided on the lower surface side of the bottom wall 42 of the case member 4. The case member 4 and the metal case 5 are fastened together by inserting and screwing bolts 9 into the wedge through holes 51 and the screw hole portions 45. A sealing property between the case member 4 and the metal case 5 can be improved by bonding the peripheral wall upper surface 5a and the lower surface of the bottom wall 42 of the case member 4 by a metal-resin adhesive when performing this screw fastening process. Alternatively, an O-ring may be used instead of the metal-resin adhesive to retain the sealing property.

The present invention can be preferably used for semiconductor modules having a base plate, substrates disposed on one surface of the base plate, and a case member surrounding the substrates.

What is claimed is:

1. A semiconductor module, comprising:
a base plate whose one surface is formed with a fin region in which a cooling fin is provided;
a substrate that is disposed on the other surface of the base plate and provided with a switching device; and
a case member having an internal space an opening formed in one wall of the case member so that the opening is smaller than the one surface of the base plate and larger than the fin region, wherein
the fin formed on the base plate protrudes from an internal space side to outside through the opening of the case member, and the one surface of the base plate is hermetically bonded with a surface of the one wall on the internal space side, and
the case member, the substrate, and the base plate are fixed by filling the internal space of the case member with a resin.

2. The semiconductor module according to claim 1, wherein
the case member is made of a resin.

3. The semiconductor module according to claim 2, wherein
the base plate is made of a metal, and
the base plate and the case member are hermetically bonded by a metal-resin adhesive.

4. The semiconductor module according to claim 1, wherein
a metal case is hermetically bonded to a surface of the one wall of the case member on a side opposite to the internal space.

5. The semiconductor module according to claim 4, wherein
a wall surface of the metal case is formed to be uneven, and
the metal case and the case member are hermetically bonded by performing bonding for integrating a resin and a metal by which the injection molded resin and the uneven wall surface are bonded with each other when injection molding the case member.

6. The semiconductor module according to claim 4, wherein
a through hole is provided in the one wall of the case member,
a wedge recess, which communicates with the through hole to form a wedge shape, is provided in a wall surface of the metal case that corresponds to the through hole, and
the case member and the metal case are hermetically bonded by a wedge-shaped joint that is formed by filling the through hole and the wedge recess with a resin.

7. The semiconductor module according to claim 4, wherein
a through hole is provided in the metal case,
a screw hole is provided in a wall surface of the case member that corresponds to the through hole, and
the metal case and the case member are hermetically bonded by a sealant and screw fastening.

8. The semiconductor module according to claim 2, wherein
a metal case is hermetically bonded to a surface of the one wall of the case member on a side opposite to the internal space.

9. The semiconductor module according to claim 8, wherein
a wall surface of the metal case is formed to be uneven, and
the metal case and the case member are hermetically bonded by performing bonding for integrating a resin and a metal by which the injection molded resin and the uneven wall surface are bonded with each other when injection molding the case member.

10. The semiconductor module according to claim 8, wherein
a through hole is provided in the one wall of the case member,
a wedge recess, which communicates with the through hole to form a wedge shape, is provided in a wall surface of the metal case that corresponds to the through hole, and
the case member and the metal case are hermetically bonded by a wedge-shaped joint that is formed by filling the through hole and the wedge recess with a resin.

11. The semiconductor module according to claim 8, wherein
a through hole is provided in the metal case,
a screw hole is provided in a wall surface of the case member that corresponds to the through hole, and
the metal case and the case member are hermetically bonded by a sealant and screw fastening.

12. The semiconductor module according to claim 3, wherein
a metal case is hermetically bonded to a surface of the one wall of the case member on a side opposite to the internal space.

13. The semiconductor module according to claim 12, wherein
a wall surface of the metal case is formed to be uneven, and
the metal case and the case member are hermetically bonded by performing bonding for integrating a resin and a metal by which the injection molded resin and the uneven wall surface are bonded with each other when injection molding the case member.

14. The semiconductor module according to claim 12, wherein
a through hole is provided in the one wall of the case member,
a wedge recess, which communicates with the through hole to form a wedge shape, is provided in a wall surface of the metal case that corresponds to the through hole, and
the case member and the metal case are hermetically bonded by a wedge-shaped joint that is formed by filling the through hole and the wedge recess with a resin.

15. The semiconductor module according to claim 12, wherein
a through hole is provided in the metal case,
a screw hole is provided in a wall surface of the case member that corresponds to the through hole, and
the metal case and the case member are hermetically bonded by a sealant and screw fastening.
